(19) United States
(12) Patent Application Publication
(10) Pub. No.: US 2024/0387487 A1
(43) Pub. Date: Nov. 21, 2024

(54) DISPLAY PANEL SPLICING UNIT AND DISPLAY PANEL SPLICED BY THE SAME

(71) Applicant: HUA YANG Precision Machinery Co.,Ltd, Tainan City (TW)

(72) Inventor: Yu-Jen CHEN, Taichung City (TW)

(21) Appl. No.: 18/336,595

(22) Filed: Jun. 16, 2023

(30) Foreign Application Priority Data
May 16, 2023 (TW) 112118194

(51) Int. Cl. H01L 25/16; H01L 23/538; H10K 59/90

(52) U.S. Cl. CPC H01L 25/162; H01L 23/5384; H01L 25/167; H10K 59/90

(57) ABSTRACT

A display panel splicing unit and a display panel spliced by the display panel splicing unit are provided. The display panel splicing unit has a splicing unit and a double-sided circuit substrate. The splicing unit has a transparent splicing board and a plurality of light-emitting components disposed on the transparent splicing board to emit light penetrating the transparent splicing board and thus traveling downward. The double-sided circuit substrate is not a printed circuit board (PCB) but is made of glass or ceramic and has a plurality of connecting elements for connecting wires on upper and lower surfaces of the double-sided circuit substrate, allowing a controller to be mounted thereon. Two splicing units share one double-sided circuit substrate and thus can be controlled with just one controller, allowing a display panel to be formed by splicing, using a small number of controllers.

### BACKGROUND OF THE INVENTION

### 1. Technical Field

The present disclosure relates to display panel splicing technology, and more particularly to a display panel splicing unit and a display panel spliced by the same.

### 2. Description of Related Art

Known demand for splicing display panels is currently concentrated on Micro LED display panels and OLED display panels. Display panel splicing is aimed at splicing multiple small display panels to form a large-sized panel to achieve an advantage, i.e., quick splicing-based production of large-sized panels is feasible because of the ease of manufacturing small display panels.

CN 215010856 U, which is about glass circuit board splicing technology, discloses a spliced glass circuit board comprising two glass circuit boards on which multiple connecting pieces are disposed. The connecting pieces comprise a first clamping part and a second clamping part which are made of metal and clamped onto circuits on a first glass plate and a second glass plate to constitute an electrical connection and thus form a simple and firm connecting structure.

The aforesaid prior art is characterized by connections between glass circuit boards such that circuits at adjacent glass circuit boards are connected. The technique is applicable to the scenario where multiple glass circuit boards are united and thus controlled by a master controller instead of the scenario where multiple glass circuit boards each come with a standalone controller. Furthermore, the metallic clamping parts are each disposed between the adjacent glass circuit boards, disadvantageously increasing the distance between the adjacent glass circuit boards. When applied to Micro LED display panels or OLED display panels, the aforesaid technique disadvantageously increases the pixel distance between two adjacent glass circuit boards, leading to image distortions or anomalies.

Referring to FIG. 9, to allow each glass circuit board 81 to come with a standalone controller (not shown), it will be necessary for circuits on the glass circuit boards 81 to undergo lead concentration and thus for a lead zone Z to be defined on one side of each glass circuit board 81 to accommodate a lead Z1 for connecting to a control chip (not shown). However, the lead zone Z still requires the reservation of a specific width. Likewise, the width causes an increase in the pixel distance between two adjacent glass circuit boards 81, leading to image distortions or anomalies.

Therefore, removal of the lead zone Z and retention of the glass circuit boards 81 to accommodate standalone controllers and thereby form a splicing framework can ensure a normal distance between the pixels upon completion of the splicing process and preclude image distortions or anomalies. Furthermore, the formation of the glass circuit boards that share one standalone controller has an advantage, i.e., conducive to cost reduction.

Furthermore, removal of the lead zone Z and direct formation of leads on rear sides of the glass circuit boards 81 can result in an abrupt rise in cost as well as the high likelihood of causing an approaching clamping tool to press and damage the circuits. As a result, the direct formation of leads on rear sides of the glass circuit boards 81 is not a good solution at the present moment.

### BRIEF SUMMARY OF THE INVENTION

It is an objective of the disclosure to provide a display panel splicing unit to dispense with a conventional lead zone but enable a controller to be mounted on a splicing unit so as to splice two adjacent splicing units without increasing the distance therebetween.

To achieve the above and other objectives, the disclosure provides a display panel splicing unit, comprising: a splicing unit having a transparent splicing board and a plurality of light-emitting components, the transparent splicing board having an upper surface and a lower surface, with a plurality of wires disposed on the upper surface of the transparent splicing board, the plurality of light-emitting components being disposed on the upper surface of the transparent splicing board and connected to the plurality of wires, wherein light emitted from the plurality of light-emitting components penetrates the transparent splicing board and travels downward; and a double-sided circuit substrate being not a printed circuit board (PCB), being made of glass or ceramic and having an upper surface, a lower surface and a plurality of connecting elements, with a plurality of wires disposed on the upper surface and the lower surface of the double-sided circuit substrate, the plurality of connecting elements connecting the plurality of wires on the lower surface of the double-sided circuit substrate to the plurality of wires on the upper surface of the double-sided circuit substrate, the double-sided circuit substrate being disposed on the transparent splicing board, wherein the plurality of wires on the lower surface of the double-sided circuit substrate are connected to the plurality of wires on the upper surface of the transparent splicing board.

Therefore, the disclosure dispenses with a conventional lead zone but enables a controller to be mounted on a double-sided circuit substrate of a splicing unit so as to splice two adjacent splicing units without increasing the distance therebetween.

It is another objective of the disclosure to provide a display panel spliced by a splicing unit, allowing at least two splicing units to share one controller and thereby render display panel splicing cost-efficient.

To achieve the above and other objectives, the disclosure further provides a display panel spliced by a splicing unit, comprising: at least two splicing units each having a transparent splicing board and a plurality of light-emitting components, the transparent splicing board having an upper surface and a lower surface, with a plurality of wires disposed on the upper surface of the transparent splicing board, the plurality of light-emitting components being disposed on the upper surfaces of the transparent splicing boards and connected to the plurality of wires on the upper surfaces of the transparent splicing boards, wherein light emitted from the plurality of light-emitting components penetrates the transparent splicing boards and travels downward; and at least one double-sided circuit substrate being not a printed circuit board (PCB), being made of glass or ceramic and having an upper surface, a lower surface and a plurality of connecting elements, with a plurality of wires disposed on the upper surface and the lower surface of the at least one double-sided circuit substrate, the plurality of connecting elements connecting the plurality of wires on the lower surface of the at least one double-sided circuit substrate to the plurality of wires on the upper surface of the double-sided circuit substrate, with the at least one double-sided circuit substrate connecting the at least two transparent splicing boards, wherein the plurality of wires on the lower surface of the at least one double-sided circuit substrate are connected to the plurality of wires on the upper surface of the at least two transparent splicing boards.

Therefore, the disclosure allows at least two splicing units to share one controller and thereby render display panel splicing cost-efficient.

### BRIEF DESCRIPTION OF THE SEVERAL VIEWS OF THE DRAWINGS

FIG. 1 is a perspective view of a display panel splicing unit according to a first preferred embodiment of the disclosure.

FIG. 2 is an exploded view of the display panel splicing unit according to the first preferred embodiment of the disclosure

FIG. 3 is a front view of the display panel splicing unit according to the first preferred embodiment of the disclosure.

FIG. 4 is a cross-sectional view of the display panel splicing unit taken along line 4-4 of FIG. 1.

FIG. 5 is a side view of another aspect of the first preferred embodiment of the disclosure, showing that connecting elements are lateral-surface circuits.

FIG. 6 is a cross-sectional view of a display panel spliced by a splicing unit according to an aspect of a second preferred embodiment of the disclosure.

FIG. 7 is a cross-sectional view of the display panel spliced by a splicing unit according to another aspect of the second preferred embodiment of the disclosure.

FIG. 8 is a cross-sectional view of the display panel spliced by a splicing unit according to yet another aspect of the second preferred embodiment of the disclosure.

FIG. 9 (PRIOR ART) is a perspective view of conventional glass circuit boards.

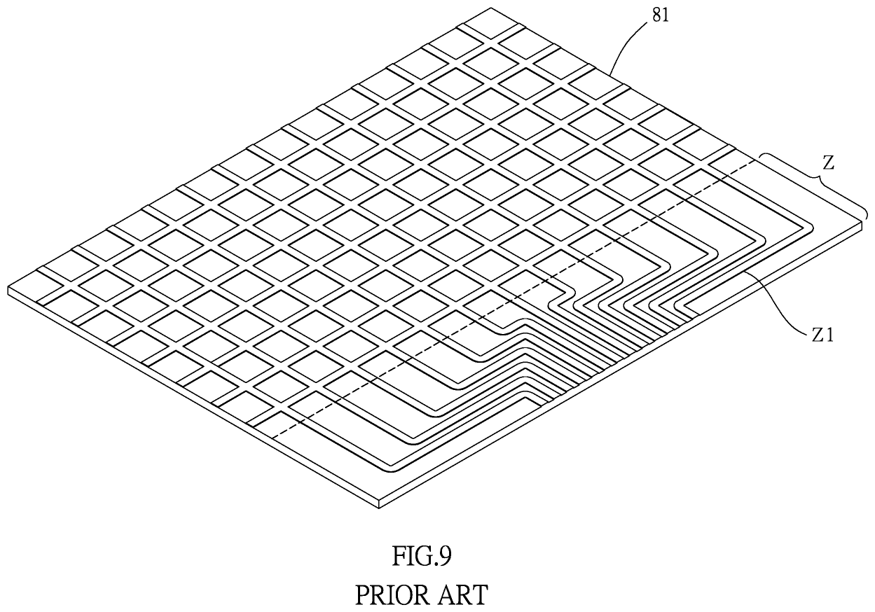

### DETAILED DESCRIPTION OF THE INVENTION

The technical features of the disclosure are hereunder illustrated with preferred embodiments, depicted with accompanying drawings, and described below.

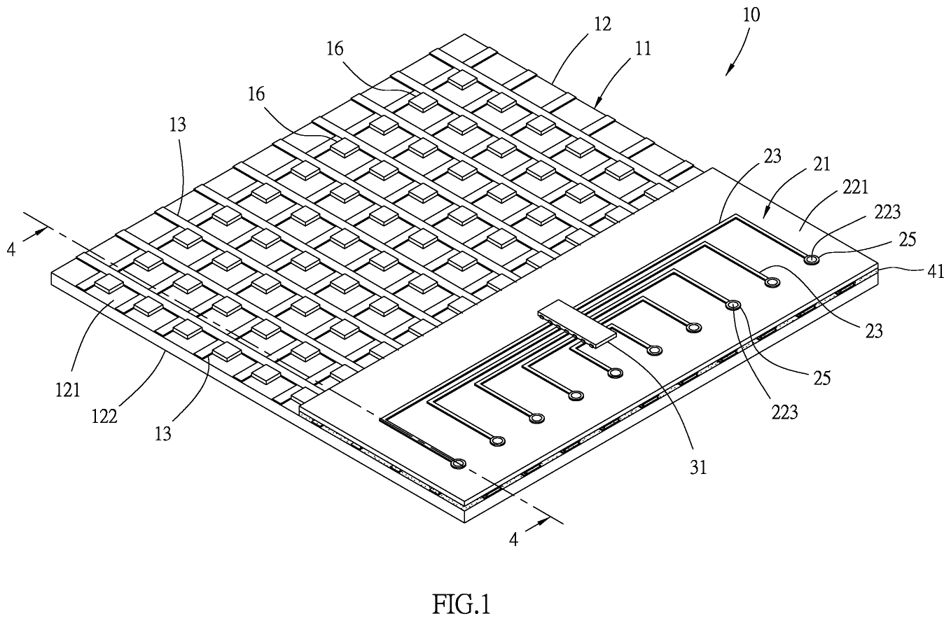

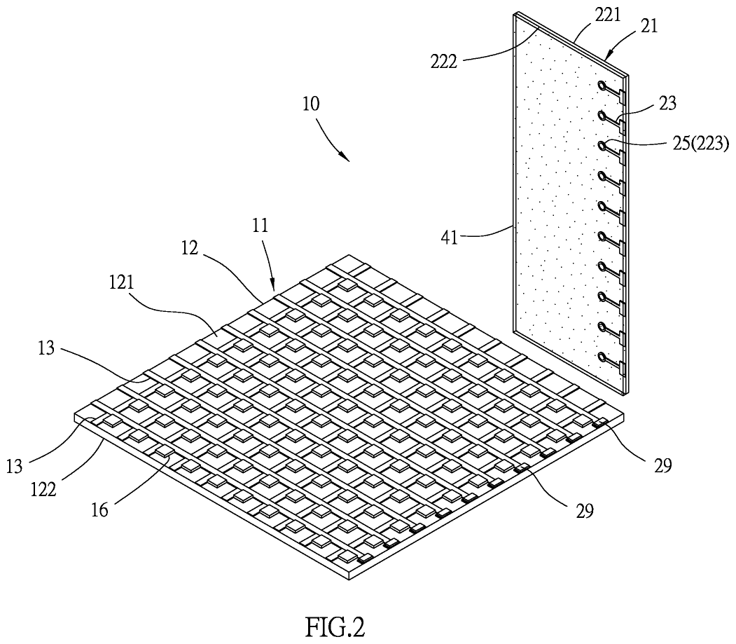

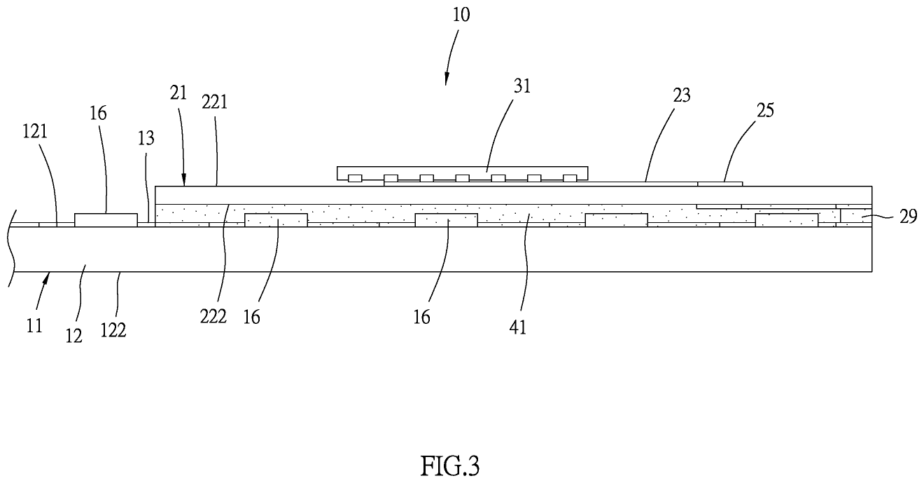

Referring to FIG. 1 through FIG. 4, a display panel splicing unit 10 according to a first preferred embodiment of the disclosure essentially comprises a splicing unit 11 and a double-sided circuit substrate 21.

The splicing unit 11 has a transparent splicing board 12 and a plurality of light-emitting components 16. The transparent splicing board 12 has an upper surface 121 and a lower surface 122. A plurality of wires 13 are disposed on the upper surface 121 of the transparent splicing board 12. The plurality of light-emitting components 16 are disposed on the upper surface 121 of the transparent splicing board 12 and connected to the plurality of wires 13. Light emitted from the plurality of light-emitting components 16 penetrates the transparent splicing board 12 to exit the lower surface 122 and travel downward. The plurality of light-emitting components 16 are exemplified by organic light-emitting diodes (OLEDs) in the first embodiment but are micro-light-emitting diodes (micro-LEDs) in practice.

The double-sided circuit substrate 21 is not a printed circuit board but is made of glass or ceramic. In this embodiment, the double-sided circuit substrate 21 is exemplified by a glass circuit board that has an upper surface 221, a lower surface 222 and a plurality of penetrating holes 223. A plurality of wires 23 are disposed on both the upper surface 221 and the lower surface 222 of the double-sided circuit substrate 21. The rim of each penetrating hole 223 is provided with a conductive substance to thereby form a connecting element 25. The plurality of wires 23 on the lower surface 222 of the double-sided circuit substrate 21 are connected by the connecting elements 25 at the rims of the penetrating holes 223 to the plurality of wires 23 on the upper surface 221 of the double-sided circuit substrate 21. The double-sided circuit substrate 21 is disposed on the transparent splicing board 12. The plurality of wires 23 on the lower surface 222 of the double-sided circuit substrate 21 are connected to the plurality of wires 13 on the upper surface 121 of the transparent splicing board 12. In this embodiment, the double-sided circuit substrate 21 and the transparent splicing board 12 are adhered together by an adhesive 41 or adhered/coupled together by any other known means, and the double-sided circuit substrate 21 is disposed above the plurality of light-emitting components 16. An electronic component, for example, a controller 31, is disposed on the upper surface 221 of the double-sided circuit substrate 21 and connected to the plurality of wires 13 on the upper surface 221 of the double-sided circuit substrate 21.

In the first embodiment, the connecting elements 25 formed at the rims of the plurality of penetrating holes 223 of the double-sided circuit substrate 21 extend from the rims of the plurality of penetrating holes 223 to the upper surface 221 and the lower surface 222 of the double-sided circuit substrate 21. The connecting elements 25 are formed by forming a thin layer of metal, for example, copper, by sputtering, and then thickening the thin layer of metal by electroplating, or are formed by any other existing known techniques. The double-sided circuit substrate 21 is a glass circuit board or ceramic substrate. The glass circuit board or ceramic substrate has advantages as follows: their surfaces can be easily attached to the transparent splicing board 12, and thus they are convenient to fix in place and easy to flatten; unlike printed circuit boards (PCB), they dispense with fastening elements, such as bolts, and rarely warp. As shown in FIG. 1 through FIG. 4, for the sake of illustration, the double-sided circuit substrate 21 is depicted as opaque to preclude excessive, overlapping lines, and thus the plurality of wires 23 and the controller 31 disposed on the double-sided circuit substrate 21 are clearly shown. However, in practice, the double-sided circuit substrate 21 is transparent.

Moreover, a conductive adhesive 29 is disposed between the double-sided circuit substrate 21 and the transparent splicing board 12 and adapted to connect the plurality of wires 23 on the lower surface 222 of the double-sided circuit substrate 21 to the plurality of wires 13 on the upper surface 121 of the transparent splicing board 12. The conductive adhesive 29 is an anisotropic conductive film (ACF) or colloid containing gold nanoparticles. The connection is not necessarily achieved by the conductive adhesive 29; instead, it is feasible to weld the double-sided circuit substrate 21 to the wires 13 on the transparent splicing board 12 by laser welding or place an alloy with a low melting point between the double-sided circuit substrate 21 and the wires 13 on the transparent splicing board 12 and then heat and melt the alloy to achieve the connection. Alternatively, the connection is achieved by any other existing known techniques.

The structural features of the first embodiment are described above. The operation state and advantages of the first embodiment are described below.

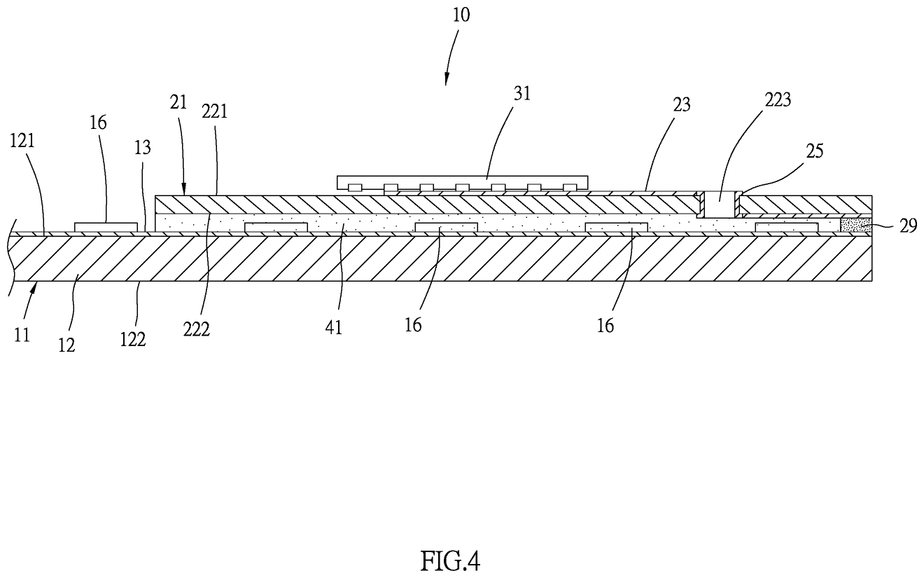

As shown in FIG. 4, by connecting the plurality of wires 23 on the upper surface 221 and the lower surface 222 of the double-sided circuit substrate 21 and connecting the plurality of wires 23 on the lower surface 222 of the double-sided circuit substrate 21 to the plurality of wires 13 on the upper surface 121 of the transparent splicing board 12, the controller 31 controls the plurality of light-emitting components 16 to emit light and thereby achieve a displaying purpose. In the first embodiment, the splicing unit 11 and another splicing unit are spliced to form a large-sized display panel (see the description of the second embodiment below).

In the first embodiment, since the plurality of wires 13 on the transparent splicing board 12 are connected to the plurality of wires 23 on the double-sided circuit substrate 21, the circuit connected to the controller 31 can be directly disposed on the double-sided circuit substrate 21, and the controller 31 can be disposed on the double-sided circuit substrate 21, i.e., on the rear sides of display panels of the transparent splicing board 12. Therefore, the disclosure dispenses with a conventional lead zone and thus does not cause an increase in the distance between two adjacent splicing boards. Therefore, the disclosure is advantageous in that the distance between the light-emitting components 16 on two adjacent transparent splicing boards 12 is short enough to enable almost seamless splicing in image display.

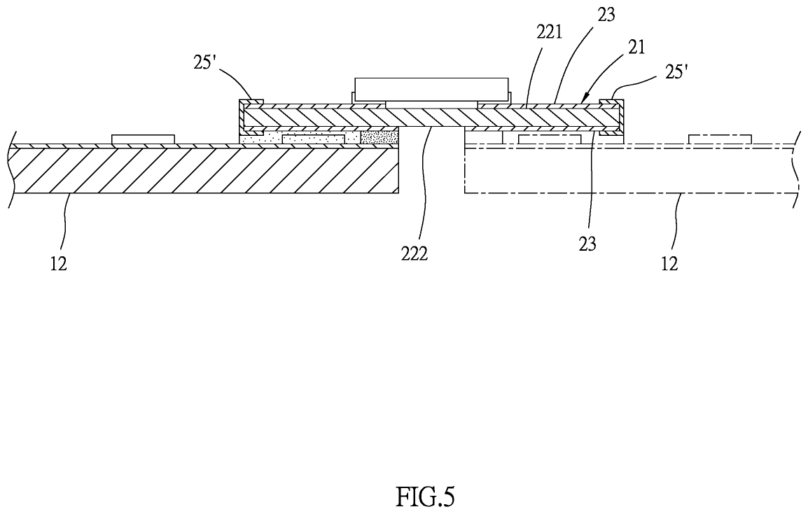

Moreover, as shown in FIG. 5, the plurality of connecting elements 25′ are replaced with lateral-surface circuits, disposed on at least one lateral surface of the double-sided circuit substrate 21, extended to the upper surface 221 and the lower surface 222 of the double-sided circuit substrate 21, and connected to the wires 23 on the upper surface 221 and the lower surface 222. As shown in FIG. 5, the double-sided circuit substrate 21 is disposed on one transparent splicing board 12 and spliced with another transparent splicing board 12 (indicated by imaginary lines).

For the sake of illustration, the plurality of light-emitting components 16 and the plurality of wires 13, 23 on the transparent splicing boards 12 and the double-sided circuit substrate 21 shown in the diagrams are not drawn according to their actual proportions and quantity. In practice, a splicing board with known specifications comes in different dimensions. Take a 9.8-inch splicing board as an example, it has 193 wires in the X-direction and 216*3 wires in the Y-direction (with 216 being multiplied by a factor of 3 because of RGB LED wires). Since the wires are densely distributed on the splicing board and thus difficult to discern and identify, the wires are schematically depicted with diagrams.

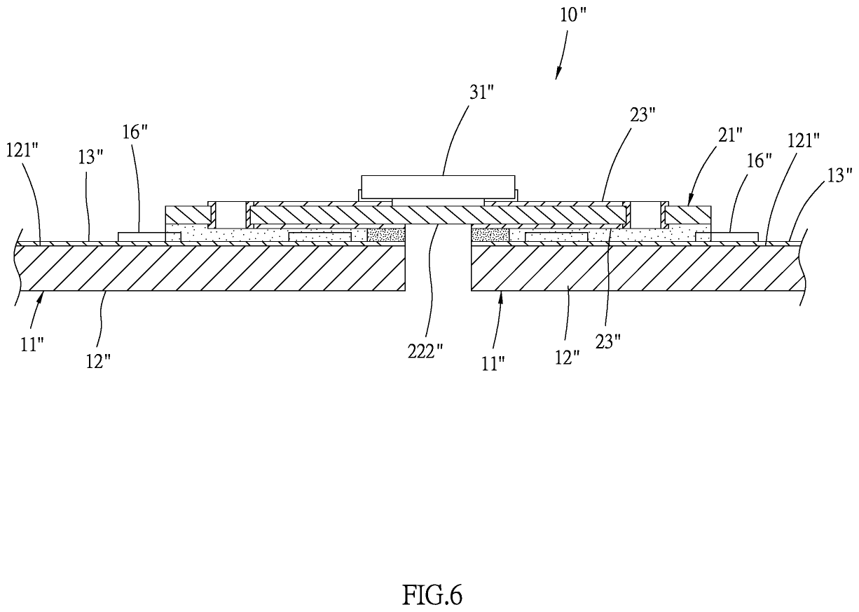

Referring to FIG. 6 through FIG. 8, a display panel 10″ spliced by a splicing unit according to a second preferred embodiment of the disclosure essentially comprises at least two splicing units 11″ and at least one double-sided circuit substrate 21″.

The at least two splicing units 11″ in the second embodiment are exemplified by two splicing units 11″. The fine structure of the splicing units 11″ in the second embodiment is substantially identical to that of the splicing unit 11 in the first embodiment and thus is not reiterated herein.

The at least one double-sided circuit substrate 21″ in the second embodiment is exemplified by a double-sided circuit substrate 21″. The fine structure of the double-sided circuit substrate 21″ in the second embodiment is distinguished from that of the double-sided circuit substrate 21 in the first embodiment by technical features as follows: The double-sided circuit substrate 21″ connects two adjacent transparent splicing boards 12″, and the plurality of wires 23″ on the lower surface 222″ of the double-sided circuit substrate 21″ are connected to the plurality of wires 13″ on the upper surfaces 121″ of the two transparent splicing boards 12″.

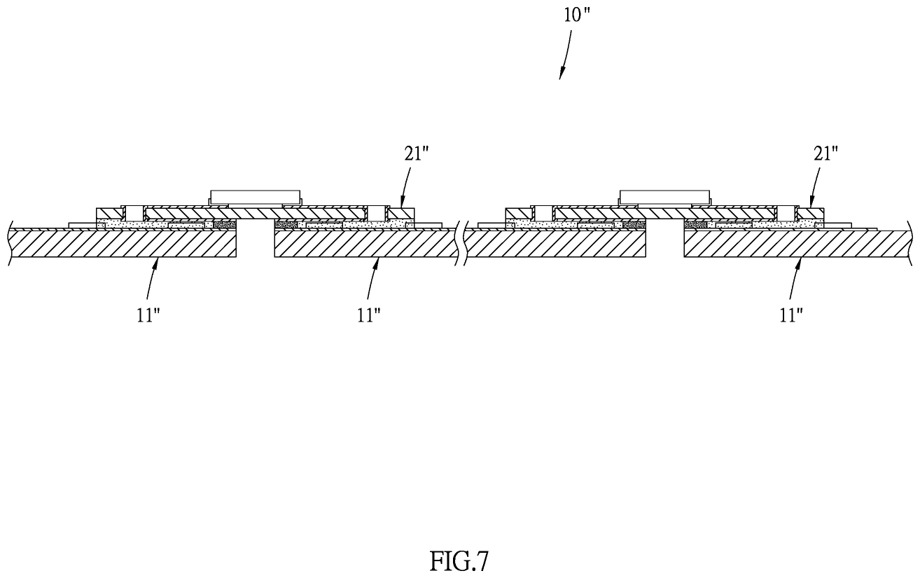

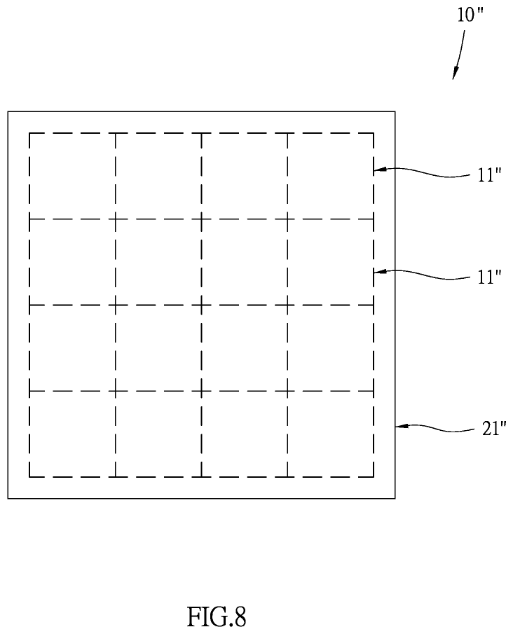

As shown in FIG. 6, two splicing units 11″ share one double-sided circuit substrate 21″. As shown in FIG. 7, three splicing units 11″ share two double-sided circuit substrates 21″. Thus, the disclosure enables manufacturers to produce large-sized display panels by splicing as needed. As shown in FIG. 8, the multiple splicing units 11″ share one double-sided circuit substrate 21″, and the size of the double-sided circuit substrate 21″ is greater than the spliced size of the splicing units 11″. Components on the splicing units 11″ are no longer shown in FIG. 8 for the sake of conciseness.

In the second embodiment, two adjacent splicing units 11″ share one double-sided circuit substrate 21″ for exemplary sake, and thus the controller 31″ on the double-sided circuit substrate 21″ controls the plurality of light-emitting components 16″ on the two splicing units 11″ to emit light. The abovementioned serves an exemplary purpose only. In practice, four or multiple splicing units 11″ share the controller 31″ on one double-sided circuit substrate 21″ as needed. Therefore, the disclosure does not require each splicing unit 11″ to work with one controller 31″ exclusive to the splicing unit 11″ but enables multiple splicing units 11″ to share one controller 31″. Therefore, the disclosure renders display panel splicing cost-efficient.

The other structural features and achievable advantages of the second embodiment are substantially identical to those of the first embodiment and thus are not reiterated herein.

What is claimed is:

1. A display panel splicing unit, comprising:
a splicing unit having a transparent splicing board and a plurality of light-emitting components, the transparent splicing board having an upper surface and a lower surface, with a plurality of wires disposed on the upper surface of the transparent splicing board, the plurality of light-emitting components being disposed on the upper surface of the transparent splicing board and connected to the plurality of wires, wherein light emitted from the plurality of light-emitting components penetrates the transparent splicing board and travels downward; and
a double-sided circuit substrate being not a printed circuit board (PCB), being made of glass or ceramic and having an upper surface, a lower surface and a plurality of connecting elements, with a plurality of wires disposed on the upper surface and the lower surface of the double-sided circuit substrate, the plurality of connecting elements connecting the plurality of wires on the lower surface of the double-sided circuit substrate to the plurality of wires on the upper surface of the double-sided circuit substrate, the double-sided circuit substrate being disposed on the transparent splicing board, wherein the plurality of wires on the lower surface of the double-sided circuit substrate are connected to the plurality of wires on the upper surface of the transparent splicing board.

2. The display panel splicing unit of claim 1, wherein the double-sided circuit substrate has a plurality of penetrating holes each having a rim provided with a conductive substance to form one said connecting element extending from the rim to the upper surface and the lower surface of the double-sided circuit substrate.

3. The display panel splicing unit of claim 2, wherein the double-sided circuit substrate is a glass circuit board, and the conductive substances provided at the rims of the plurality of penetrating holes of the double-sided circuit substrate are metal.

4. The display panel splicing unit of claim 1, wherein a conductive adhesive is disposed between the double-sided circuit substrate and the transparent splicing board to connect the plurality of wires on the lower surface of the double-sided circuit substrate to the plurality of wires on the upper surface of the transparent splicing board.

5. The display panel splicing unit of claim 1, wherein the plurality of connecting elements are a plurality of lateral-surface circuits disposed on at least one lateral surface of the double-sided circuit substrate and extended to the upper surface and the lower surface of the double-sided circuit substrate.

6. A display panel spliced by a splicing unit, comprising:
at least two splicing units each having a transparent splicing board and a plurality of light-emitting components, the transparent splicing board having an upper surface and a lower surface, with a plurality of wires disposed on the upper surface of the transparent splicing board, the plurality of light-emitting components being disposed on the upper surfaces of the transparent splicing boards and connected to the plurality of wires on the upper surfaces of the transparent splicing boards, wherein light emitted from the plurality of light-emitting components penetrates the transparent splicing boards and travels downward; and
at least one double-sided circuit substrate being not a printed circuit board (PCB), being made of glass or ceramic and having an upper surface, a lower surface and a plurality of connecting elements, with a plurality of wires disposed on the upper surface and the lower surface of the at least one double-sided circuit substrate, the plurality of connecting elements connecting the plurality of wires on the lower surface of the at least one double-sided circuit substrate to the plurality of wires on the upper surface of the double-sided circuit substrate, with the at least one double-sided circuit substrate connecting the at least two transparent splicing boards, wherein the plurality of wires on the lower surface of the at least one double-sided circuit substrate are connected to the plurality of wires on the upper surface of the at least two transparent splicing boards.

7. The display panel spliced by a splicing unit according to claim 6, wherein the at least one double-sided circuit substrate has a plurality of penetrating holes each having a rim provided with a conductive substance to form one said connecting element extending from the rim to the upper surface and the lower surface of the at least one double-sided circuit substrate.

8. The display panel spliced by a splicing unit according to claim 7, wherein the at least one double-sided circuit substrate is a glass circuit board, and the conductive substances provided at the rims of the plurality of penetrating holes of the at least one double-sided circuit substrate are metal.

9. The display panel spliced by a splicing unit according to claim 6, wherein a conductive adhesive is disposed between the at least one double-sided circuit substrate and each of the at least two transparent splicing boards to connect the plurality of wires on the lower surface of the at least one double-sided circuit substrate to the plurality of wires on the upper surfaces of the at least two transparent splicing boards.

10. The display panel spliced by a splicing unit according to claim 6, wherein the plurality of connecting elements are a plurality of lateral-surface circuits disposed on at least one lateral surface of the double-sided circuit substrate and extended to the upper surface and the lower surface of the double-sided circuit substrate.
